(19) United States
(12) Patent Application Publication
(10) Pub. No.: US 2008/0093719 A1
(43) Pub. Date: Apr. 24, 2008

(54) CHIP PACKAGE STRUCTURE

(75) Inventors: Yan-Yi Wu, Shanghai (CN); Xin-Ming Li, Shanghai (CN); Chih-Lung Huang, Shanghai (CN)

Correspondence Address: J C PATENTS, INC., 4 VENTURE, SUITE 250, IRVINE, CA, 92618, US

(73) Assignees: ChipMOS TECHNOLOGIES(SHANGHAI) LTD., Shanghai (CN); ChipMOS Technologies (Bermuda) LTD., Hamilton (BM)

(21) Appl. No.: 11/465,347

(22) Filed: Aug. 17, 2006

(30) Foreign Application Priority Data
Jul. 12, 2006 (TW) 95125413

(51) Int. Cl. H01L 23/495

(52) U.S. Cl. 257/676; 257/E23.031

(57) ABSTRACT

A chip package structure including a chip, a leadframe, multiple bonding wires and an encapsulant is provided. The chip has an active surface and multiple contacts. The contacts are located on one side of the active surface. The chip is fixed under the leadframe. The leadframe has multiple first inner leads located on the active surface, and multiple second leads, wherein one end of each first inner lead and one end of each second inner lead are at near outside of one of the contacts. The bonding wires respectively connect the first inner leads and the second inner leads to the contacts. The encapsulant wraps the chip, the first inner leads, the second inner leads and the bonding wires. Because the contacts are located on one side of the active surface, the possibility of collapse of the bonding wires is reduced.

### CROSS-REFERENCE TO RELATED APPLICATION

This application claims the priority benefit of Taiwan application serial no. 95125413, filed Jul. 12, 2006. All disclosure of the Taiwan application is incorporated herein by reference.

### BACKGROUND OF THE INVENTION

1. Field of Invention

The present invention relates to chip package structure. More particularly, the present invention relates to a chip package structure having a lead frame.

2. Description of Related Art

In semiconductor fabrication, the integrated circuit (IC) is fabricated basically by three stages: IC design; IC process; and IC package.

In fabricating IC, the chip is fabricated in completion by the steps of processing a wafer, forming the IC, sawing the wafer, and so on. The wafer has an active surface, which is generally referred to a surface of the wafer having the active device. After integrated circuit of the wafer is accomplished, the active surface of the wafer is further implemented with multiple bonding pads. The chip, which has been finally cut from the wafer, can be electrically connected to a carrier by the bonding pads. The carrier is, for example, a leadframe or a package substrate. The chip can be connected to the carrier by a manner of wire bonding or flip chip bonding, so that the bonding pads of the chip can be electrically connected to the connection terminal of the carrier and then a chip packaging structure is formed.

FIG. 1 is a cross-section view, schematically illustrating a conventional chip packaging structure. In FIG. 1, the chip package structure 100 is a lead on chip (LOC) of chip packaging structure, which includes a chip 110, a leadframe 120, several bonding wires 130, and an encapsulant 140. The chip 110 includes multiple bonding pad 112, wherein the bonding pads 112 are located the active surface 110a of the chip 110, and the bonding pads 112 are located at the central region of the active surface. The leadframe 120 has several inner leads 122. The inner leads 122 are disposed on the active surface 110a and distributed along the periphery of the active surface 10a. The bonding wires 130 are disposed between the bonding pads 112 and the inner leads, for electrically collecting the bonding pads 112 to the inner leads 122. The encapsulaant 140 wraps the chip 110, the inner leads 122, and the bonding wires 130.

Since the inner leads 122 are distributed along the periphery of the chip 110, the bonding wires 130 have longer length and easy in collapse causing electric short circuit. Further, since the bonding wires 130 have longer length, during the encapsulant 140 being formed, the bonding wires 130 are easily broken by the liquid encapsulant 140 being filled into the mold, causing an electric break of circuit. In this point for the packaging process, the conventional design of the chip package structure 100 is easily causing low production yield.

### SUMMARY OF THE INVENTION

The invention provides a chip package structure for reducing the possibility of bonding wire collapse.

The invention provides a chip package structure includes a chip, a leadframe, multiple bonding wires and an encapsulant. The chip has an active surface and multiple first contacts. The first contacts are located on one side of the active surface. The chip is fixed under the leadframe. The leadframe has multiple first inner leads and multiple second inner leads. The inner leads are located on the active surface, and one end of each first inner lead and one end of each second inner lead are at near outside of one of the first contacts. The bonding wires respectively connect the first inner leads and the second inner leads to the first contacts. The encapsulant wraps the chip, the first inner leads, the second inner leads and the bonding wires.

In an embodiment of the invention, the second inner leads are located at near outside of the chip and adjacent to the first contacts. In addition, the second inner leads and the chip can be coplanar.

In an embodiment of the invention, the leadframe can further include at least one first bus bar and at least one second bus bar, respectively located between the first inner leads and the first contacts, and between the second inner leads and the first contacts. The second bus bar and the second inner leads may have height difference and the second bus bar is a down-set design. In addition, chip package structure can further include at least one second binding wire and at least one third bonding wire. The chip can further include at least one second contact. The second contact and the first contacts are at the same side of the active surface. The second bonding wire connects between the second contact and the first bus bar, and the third bonding wire connects between the first bus bar and one of the first inner leads. In addition, the chips package structure can further include at least one fourth bonding wire and at least one fifth bonding wire. The chip can further include at least one third contact. The third contact and the first contacts are at the same side of the active surface. The fourth bonding wire connects between the third contact and the second bus bar, and the fifth bonding wire connected between the second bus bar and one of the second inner leads. In addition, in the chips package structure, for example, the first bus bar can be over the active surface and the second bus bar can be at the outside of the chip.

In the invention, the contacts of the chip are at one side of the active surface. The first inner leads are disposed on the active surface, and each one end of the first inner leads and the second inner leads is at the near outside of contacts. As a result, the invention can reduce the distance between the inner leads, that are first inner leads and the second inner leads, and the contacts. The invention can reduce the length of bonding wires connected between the contacts and the inner leads, so that the possibility of bonding wire collapse can be reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view, schematically illustrating a conventional chip package structure.

FIG. 2 is a cross-sectional view, schematically illustrating a chip package structure, according to an embodiment of the invention.

FIG. 3 is a drawing, schematically illustrating a process for fabricating a chip package structure, according to an embodiment of the invention.

FIG. 4 is a cross-sectional view, schematically illustrating a chip package structure, according to an embodiment of the invention.

FIG. 5 is a cross-sectional view, schematically illustrating a chip package structure, according to an embodiment of the invention.

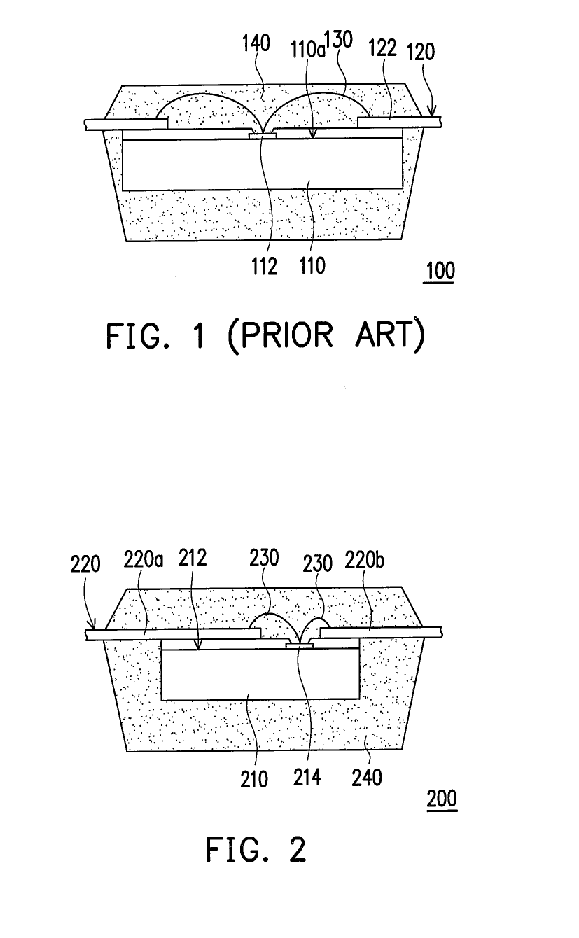

### DESCRIPTION OF THE PREFERRED EMBODIMENTS

FIG. 2 is a cross-sectional view, schematically illustrating a chip package structure, according to an embodiment of the invention. Referring to FIG. 2, the chip package structure 200 includes a chip 210, a leadframe 220, multiple first bonding wires 230 and an encapsulant 240. The chip 210 has an active surface 212 and multiple first contacts 214, located at one side of the active surface 212. In more detail, the first contacts 214 are adjacent to the active surface 212 at one side.

The chip 210 is fixed under the leadframe 220. The leadframe 220 has multiple first inner leads 220a and multiple second inner leads 220b. The first inner leads 220a are located on the active surface 212. One end of each first inner lead 220a and one end of each second lead 220b are adjacent to corresponding one of the first contacts 214.

In FIG. 2, although the first inner leads 220a and the second inner leads 220b are located above the active surface 212, FIG. 2 is just for describing the invention but not for limiting the invention. In other embodiments of the invention, the second inner leads 220b can be at near outside of the chip 210.

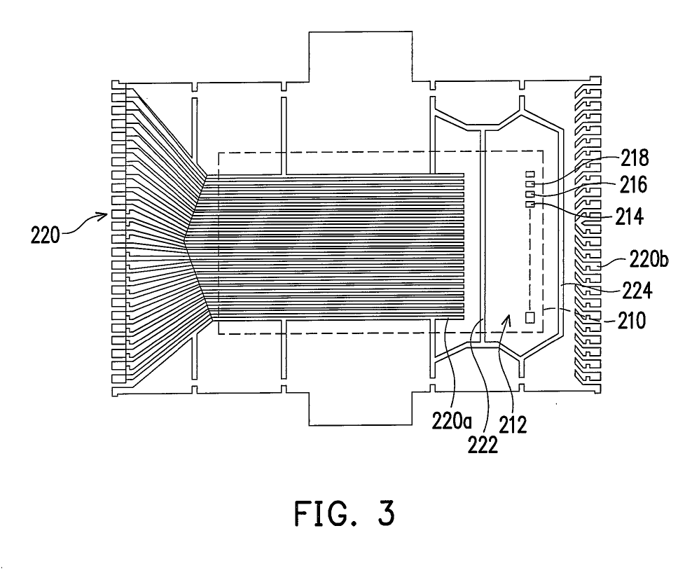

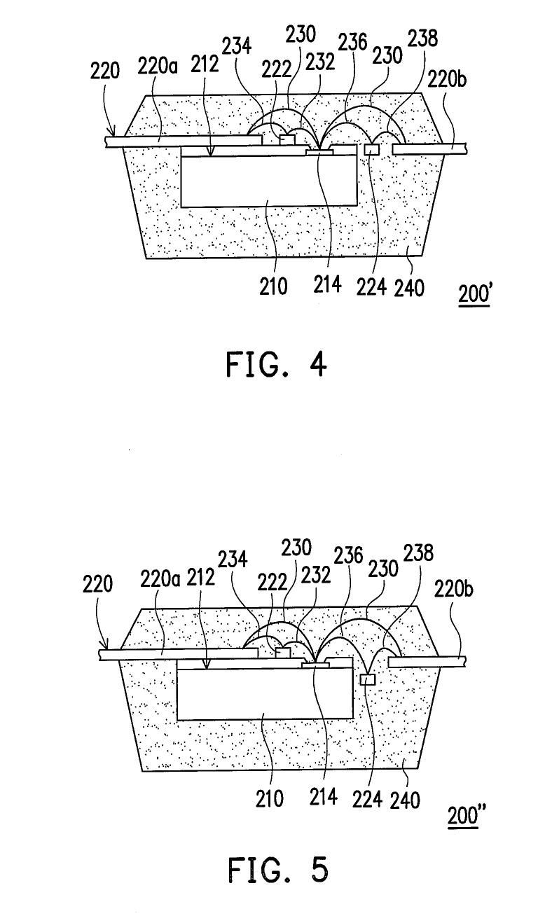

FIG. 3 is a drawing, schematically illustrating a process for fabricating a chip package structure, according to an embodiment of the invention. In FIG. 3, a chip 210 is provided. Then, a leadframe 220 without being cut is disposed on the active surface 212 of the chip 210, wherein the first inner leads 220a of the leadframe 220 is disposed over the active surface 212, the second inner leads 220b are disposed at near outside of the chip 210. In addition, each one end of the first inner leads 220a and the second inner leads 220b is located at near outside of the first contact 214. The second inner leads 220b is on the same plane of the active surface 212 of the chip 210 as a coplanar arrangement, for example. Then, a chip package structure 200′, as shown in FIG. 4, is formed by the subsequent processes of bonding process, encapsulating process, and cutting process for cutting the leadframe 220, which is not cut yet. FIG. 4 is a cross-sectional view, schematically illustrating a chip package structure, according to an embodiment of the invention. For easy descriptions, the structure of the encapsulant 240 can be schematically seen in FIG. 4. In FIG. 4, a portion of the first bonding wire 230 is electrically connected between the first inner leads 220a and the first contacts 214. The other portion of the first bonding wire 230 is electrically connected between the second inner leads 220b and the first contacts 214.

Remarkably, in the foregoing implementation, the first inner leads 220a are disposed above the active surface 212, the second inner leads 220b are disposed at near outside of the chip 210, and each one end of the inner leads 220a and the second inner leads 220b is at near outside of the first contact 214. As a result, the invention in comparing with conventional technology can at least reduce the distance between the first inner leads 220a and the first contacts 214, and reduce the distance between the second inner leads 220b and the first contacts 214.

In addition, chip 210 can further include at least one second contact 216 and at least one third contact 218. The second contacts 216 can be a grounding pad or a power source pad. The third contact 218 can be grounding pad or a power source pad. Remarkably, the first contacts 214, the second contact 216, and the third contact 218 are located at the same side of the active surface 212.

When the chip 210 has at least one second contact 216 and at least one third contact 218, the chip package structure 200′ can further include at least one second bonding wire 232, at least one third bonding wire 234, at least one fourth bonding wire 236, and at least one fifth bonding wire 238. In addition, the leadframe 220 can further include at least one first bus bar 222 and at least one second bus bar 224. The first bus bar 222 is located above the active surface and located between the first inner leads 220a and the first contacts 214. The second bus bar 224 is located at near outside of the chip 210, and located between the second inner lead 220b and the first contact 214.

As a result, in the embodiment, the second bonding wire 232 can be connected between the second contact 216 and the first bus bar 222. The third bonding wire 234 can be connected between the first bus bar 222 and one of the first inner leads 220a. In addition, for an embodiment, the fourth bonding wire 236 can be connected between the third contact 218 and the second bus bar 224, and the fifth bonding wire 238 can be connected between the second bus bar 224 and one of the inner leads 220b. As a result, in the embodiment, the bonding wires can be formed via the first bus bar 222 and the bus bar 224, that are the first bonding wire 230, the second bonding wire 232, the third bonding wire 234, the fourth bonding wire 236, and the fifth bonding wire 238. The bonging process can be more easily performed.

In addition, in an embodiment of the invention, it can have a height difference between the second bus bar 224 and the second inner leads 220b. FIG. 5 is a cross-sectional view, schematically illustrating a chip package structure, according to an embodiment of the invention. In FIG. 5, the chip package structure 200″ is similar to the chip package structure 200′. The difference between them is that the second bus bar 224 of the chip package structure 200″ is designed by down-set manner, so as to maintain a height difference from the second inner leads 220b. As a result, in the embodiment, the complexity of bonding process can be simplified by the second bus bar 224. Further, the down-set design can reduce the gap between the second inner leads 220b and the chip 210.

In comparing with conventional technology, the contacts of the invention are at one side of the active surface, the first inner leads are disposed above the active surface. One end of each of the first inner leads and one end of each of the second inner leads are located at near outside of the contacts. As a result, the invention can reduce the distance between the inner leads (that are first inner leads and the second inner leads) and the contacts. The shorter bonding wires of the invention can be used to connect inner leads to the corresponding one of the contacts.

As described above, since the length of the bonding wire is reduced, the possibility of wire collapse can be reduced, and the possibility of broken wire due to filling the liquid encapsulant in to the mold can be reduced, too. The structure design of the embodiment of the invention can improve the yield in chip packaging process.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A chip package structure, comprising:
a chip, having an active surface and a plurality of first contacts disposed on the active surface, the first contacts being located at one side of the active surface;
a leadframe, the chip being adhered under the leadframe, the leadframe having a plurality of first inner leads and a plurality of second inner leads, wherein the first inner leads are located on the active surface and each one end of the first inner leads and the second inner leads is located at near outside of the first contacts;
a plurality of first bonding wires, respectively connected between the first inner leads and the first contacts, and between the second inner leads and the first contacts; and
an encapsulant, wrapping the chip, the first inner leads, the second inner leads and the first bonding wires.

2. The chip package structure of claim 1, wherein the second inner leads are located at near outside of the chip and adjacent to the first contacts.

3. The chip package structure of claim 2, wherein the second inner leads and the chip are coplanar.

4. The chip package structure of claim 1, wherein the leadframe further comprises at least one first bus bar and at least one second bus bar, respectively located between the first inner leads and the first contacts, and between the second inner leads and the first contacts.

5. The chip package structure of claim 4, further comprising at least one second bonding wire and at least one third bonding wire, the chips further comprising at least one second contact, wherein the second contact and the first contacts are located at the same side of the active surface, the second bonding wire is connected between the second contact and the first bus bar, and the third bonding wire is connected between the first bus bar and one of the first inner leads.

6. The chip package structure of claim 4, further comprising at least one fourth bonding wire and at least one fifth bonding wire, the chips further comprising at least one third contact, wherein the third contact and the first contacts are located at the same side of the active surface, the fourth bonding wire is connected between the third contact and the second bus bar, and the fifth bonding wire is connected between the second bus bar and one of the second inner leads.

7. The chip package structure of claim 4, wherein the first bus bar is located above the active surface, and the second bus bar is located at outside of the chip.

8. The chip package structure of claim 5, wherein a height difference is between the second bus bar and the second inner leads, and the second bus bar is a down-set design.
